(19) United States
(12) Patent Application Publication
(10) Pub. No.: US 2017/0288122 A1
(43) Pub. Date: Oct. 5, 2017

(54) BAW RESONATOR HAVING THIN SEED LAYER

(71) Applicant: Avago Technologies General IP (Singapore) Pte. Ltd., Singapore (SG)

(72) Inventors: Qiang Zou, Fort Collins, CO (US); Chris Feng, Fort Collins, CO (US); Phil Nikkel, Loveland, CO (US); John Choy, Westminster, CO (US)

(21) Appl. No.: 15/140,777

(22) Filed: Apr. 28, 2016

Related U.S. Application Data
(63) Continuation-in-part of application No. 15/084,278, filed on Mar. 29, 2016.

(51) Int. Cl. H01L 41/047; H01L 41/107; H03H 9/56; H01L 41/04

(52) U.S. Cl. CPC H01L 41/0471; H01L 41/04; H01L 41/107; H03H 9/56

(57) ABSTRACT

A bulk acoustic wave (BAW) resonator comprises: a seed layer disposed over a substrate; a first electrode disposed over the seed layer; and a second electrode disposed over a piezoelectric layer. The seed layer has a thickness in the range of approximately 30 Å to approximately 150 Å.

### CROSS REFERENCE TO RELATED APPLICATION

The present application is a continuation-in-part application under 37 C.F.R. §1.53(b) of commonly owned U.S. patent application Ser. No. 15/084,278, entitled “Temperature Compensated BAW resonator device having Thin Seed Interlayer,” filed on Mar. 29, 2016. The entire disclosure of U.S. patent application Ser. No. 15/084,278 is hereby specifically incorporated by reference.

### BACKGROUND

Electrical resonators are widely incorporated in modern electronic devices. For example, in wireless communications devices, radio frequency (RF) and microwave frequency resonators are used as filters, such as ladder filters having electrically connected series and shunt resonators formed in a ladder structure. The filters may be included in a duplexer, for example, connected between a single antenna and a receiver and a transmitter for respectively filtering received and transmitted signals.

Various types of filters use mechanical resonators, such as bulk acoustic wave (BAW) and surface acoustic wave (SAW) resonators. A BAW resonator, for example, is an acoustic stack that generally includes a layer of piezoelectric material between two electrodes. Acoustic waves achieve resonance across the acoustic stack, with the resonant frequency of the waves being determined by the materials in the acoustic stack and the thickness of each layer (e.g., piezoelectric layer and electrode layers). Types of BAW resonators include a film bulk acoustic resonator (FBAR), which uses an air cavity for acoustic isolation, and a solidly mounted resonator (SMR), which uses an acoustic mirror for acoustic isolation, such as a distributed Bragg reflector (DBR). FBARs, like other BAW devices, may be configured to resonate at frequencies in GHz ranges, and are relatively compact, having thicknesses on the order of microns and length and width dimensions of hundreds of microns. This makes FBARs well-suited to many applications in high-frequency communications.

Generally, a BAW resonator has a layer of piezoelectric material between two conductive plates (electrodes), which may be formed on a thin membrane. The piezoelectric material may be a thin film of various materials, such as aluminum nitride (AlN). Thin films made of AlN are advantageous since they generally maintain piezoelectric properties at a high temperature (e.g., above 400° C.). The acoustic stack of a BAW resonator comprises a first electrode, a piezoelectric layer disposed over the first electrode, and a second electrode disposed over the piezoelectric layer. The acoustic stack is disposed over the acoustic reflector. The series resonance frequency (Fₛ) of the BAW resonator is the frequency at which the dipole vibration in the piezoelectric layer of the BAW resonator is in phase with the applied electric field. On a Smith Chart, the series resonance frequency (Fₛ) is the frequency at which the Q circle crosses the horizontal axis. As is known, the series resonance frequency (Fₛ) is governed by, inter alia, the total thickness of the layers of the acoustic stack. As can be appreciated, as the resonance frequency increases, the total thickness of the acoustic stack decreases. Moreover, the bandwidth of the BAW resonator determines the thickness of the piezoelectric layer. Specifically, for a desired bandwidth a certain electromechanical coupling coefficient (kt²) is required to meet that particular bandwidth requirement. The kt² of a BAW resonator is influenced by several factors, such as the dimensions (e.g., thickness), composition, and structural properties of the piezoelectric material and electrodes. Generally, for a particular piezoelectric material, a greater kt² requires a greater thickness of piezoelectric material. As such, once the bandwidth is determined, the kt² is set, and the thickness of the piezoelectric layer of the BAW resonator is fixed. Accordingly, if a higher resonance frequency for a particular BAW resonator is desired, any reduction in thickness of the layers in the acoustic stack cannot be made in the piezoelectric layer, but rather must be made by reducing the thickness of the electrodes.

While reducing the thickness of the electrodes of the acoustic stack provides an increase in the resonance frequency of the BAW resonator, this reduction in the thickness of the electrodes comes at the expense of performance of the BAW resonator. For example, reduced electrode thickness results in a higher sheet resistance in the electrodes of the acoustic stack. The higher sheet resistance results in a higher series resistance (Rs) of the BAW resonator and an undesired lower quality factor around series resonance frequency Fs (Qs). Moreover, as electrode thickness decreases, the acoustic stack becomes less favorable for high parallel resistance (Rp) and as a result the quality factor around parallel resonance frequency Fp (Qp) is undesirably reduced.

What is needed, therefore, is a BAW resonator structure that addresses at least some of the noted shortcomings of known BAW resonator devices described above.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1 is a cross-sectional diagram illustrating a BAW resonator device, including and thin seed interlayer beneath a lower electrode according to a representative embodiment.

FIG. 2A is a diagram showing effective coupling coefficients of BAW resonator devices as a function of seed layer thickness.

FIG. 2B is a diagram showing standard deviations of effective coupling coefficients across BAW resonator device wafers.

FIG. 3 is a cross-sectional diagram illustrating a BAW resonator device, including an electrode with a buried temperature compensating layer and thin seed interlayer according to a representative embodiment.

FIG. 4A is a diagram showing effective coupling coefficients of BAW resonator devices as a function of seed interlayer thickness, according to representative embodiments.

FIG. 4B is a diagram showing standard deviations of effective coupling coefficients across BAW resonator device wafers as a function of seed interlayer thickness.

FIG. 5A is a diagram showing resistance at parallel resonance (Rp) as a function of seed interlayer thickness, according to representative embodiments.

FIG. 5B is a diagram showing resistance at series resonance (Rs) as a function of seed interlayer thickness, according to representative embodiments.

### DETAILED DESCRIPTION

In the following detailed description, for purposes of explanation and not limitation, representative embodiments disclosing specific details are set forth in order to provide a thorough understanding of the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparatuses and methods may be omitted so as to not obscure the description of the representative embodiments. Such methods and apparatuses are clearly within the scope of the present teachings.

Relative terms, such as “above,” “below,” “top,” “bottom,” “upper” and “lower” may be used to describe the various elements' relationships to one another, as illustrated in the accompanying drawings. These relative terms are intended to encompass different orientations of the device and/or elements in addition to the orientation depicted in the drawings. For example, if the device were inverted with respect to the view in the drawings, an element described as “above” another element, for example, would now be “below” that element. Similarly, if the device were rotated by 90° with respect to the view in the drawings, an element described “above” or “below” another element would now be “adjacent” to the other element; where “adjacent” means either abutting the other element, or having one or more layers, materials, structures, etc., between the elements.

A variety of devices, structures thereof, materials and methods of fabrication are contemplated for the BAW resonators of the apparatuses of the present teachings. Various details of such devices and corresponding methods of fabrication may be found, for example, in one or more of the following U.S. patent publications: U.S. Pat. No. 6,107,721, to Lakin; U.S. Pat. Nos. 5,587,620, 5,873,153, 6,507,983, 7,388,454, 7,629,865, 7,714,684, and 8,436,516 to Ruby et al.; U.S. Pat. Nos. 7,369,013, 7,791,434 8,188,810, and 8,230,562 to Fazzio, et al.; U.S. Pat. No. 7,280,007 to Feng et al.; U.S. Pat. Nos. 8,248,185, and 8,902,023 to Choy, et al.; U.S. Pat. No. 7,345,410 to Grannen, et al.; U.S. Pat. No. 6,828,713 to Bradley, et al.; U.S. Pat. Nos. 7,561,009 and 7,358,831 to Larson, III et al.; U.S. Pat. No. 9,197,185 to Zou, et al., U.S. Patent Application Publication No. 20120326807 to Choy, et al.; U.S. Patent Application Publications Nos. 20110180391 and 20120177816 to Larson III, et al.; U.S. Patent Application Publication No. 20070205850 to Jamneala et al.; U.S. Patent Application Publication No. 20110266925 to Ruby, et al.; U.S. Patent Application Publication No. 20130015747 to Ruby, et al.; U.S. Patent Application Publication No. 20130049545 to Zou, et al.; U.S. Patent Application Publication No. 20140225682 to Burak, et al.; U.S. Patent Publication No. 20140132117 to John L. Larson III; U.S. Patent Publication Nos.: 20140118090 and 20140354109 John L. Larson III, et al.; U.S. Patent Application Publication Nos. 20140292150, and 20140175950 to Zou, et al.; and U.S. Patent Application Publication No. 20150244347 to Feng, et al. The entire disclosure of each of the patents, and patent application publications listed above are hereby specifically incorporated by reference herein. It is emphasized that the components, materials and methods of fabrication described in these patents and patent applications are representative, and other methods of fabrication and materials within the purview of one of ordinary skill in the art are also contemplated.

According to various representative embodiments, a bulk acoustic wave (BAW) resonator comprises: a seed layer disposed over a substrate; a first electrode disposed over the seed layer; and a second electrode disposed over a piezoelectric layer. The seed layer has a thickness in the range of approximately 30 Å to approximately 150 Å. In certain embodiments, the seed layer has a thickness in the range of approximately 30 Å to approximately 60 Å. In certain embodiments, the piezoelectric layer comprises scandium (Sc) doped aluminum nitride (ASN), doped in the range of approximately 3.0 atomic percent (3%) to approximately 18.0 atomic percent (18%). In certain embodiments, the seed layer is doped with scandium in the range of approximately 3% (where “%” refers to atomic percent) to approximately 18.0%.

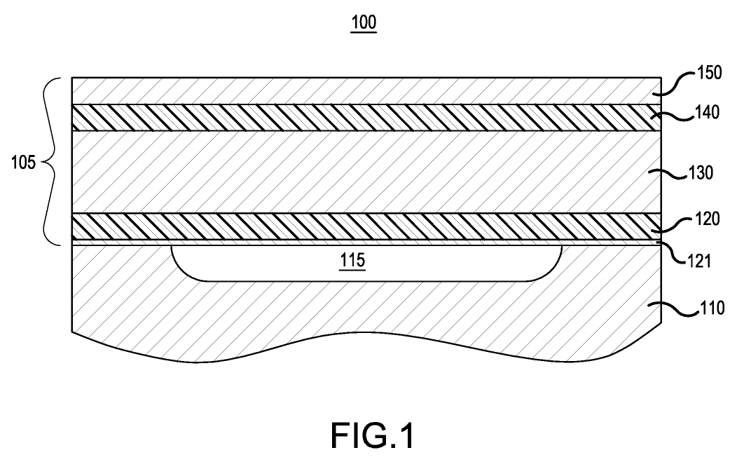

FIG. 1 is a cross-sectional view of a BAW resonator device 100 according to a representative embodiment. Notably, the various components of the BAW resonator device comprise materials, have dimensions, and are formed using methods described in one or more of the above-incorporated commonly owned patent applications, patent application publications, and patents described above. Often the details of these materials, dimensions, and methods of fabrication are not described to avoid obscuring the details of the various representative embodiments described below.

Referring to FIG. 1, illustrative BAW resonator device 100 comprises an acoustic stack 105 disposed over substrate 110. The substrate 110 may be formed of various types of materials compatible with wafer-scale processes, such as silicon (Si), gallium arsenide (GaAs), indium phosphide (InP), silicon dioxide, alumina, or the like, thus reducing the cost of the final part. In the depicted embodiment, the substrate 110 defines a cavity 115 formed beneath the acoustic stack 105 to provide acoustic isolation, such that the acoustic stack 105 is suspended over an air space to enable mechanical movement. In alternative embodiments, the substrate 110 may be formed with no cavity 115, for example, using SMR technology. For example, the acoustic stack 105 may be formed over an acoustic mirror or a distributed Bragg reflector (DBR) (not shown), having alternating layers of high and low acoustic impedance materials, formed in or on the substrate 110. An acoustic mirror may be fabricated according to various techniques, an example of which is described in U.S. Pat. No. 7,358,831 to Larson, III, et al., the disclosure of which is hereby incorporated by reference in its entirety.

The acoustic stack 105 comprises a seed layer 121 disposed over the substrate 110. The acoustic stack 105 also comprises a first electrode 120 (a lower electrode in depicted FIG. 1) is disposed on (i.e., directly on) the seed layer 121 to foster growth of a piezoelectric layer 130 over the first electrode 120, as described more fully below. The acoustic stack 105 further comprises a second electrode 140 disposed over the piezoelectric layer 130, and a passivation layer 150 disposed over the second electrode 140.

In a representative embodiment, the first and second electrodes 120, 140 comprise one or more (i.e., alloys of) electrically conductive materials, such as various metals compatible with wafer processes, including tungsten (W), molybdenum (Mo), aluminum (Al), platinum (Pt), ruthenium (Ru), niobium (Nb), or hafnium (HD, for example.

In the representative embodiment, piezoelectric layer 130 doped with certain rare-earth dopants (e.g., Sc, or Er) results in an enhanced piezoelectric coefficient d₃₃ in the piezoelectric layer 130. Moreover, an enhanced electromechanical coupling coefficient (sometimes referred to as the “coupling coefficient,” or the “acoustic coupling coefficient”) (kt²) is realized by incorporating one or more rare earth elements into the crystal lattice of a portion of the piezoelectric layer 130. In certain representative embodiments, the piezoelectric layer 130 comprises AlN material doped with Sc (referred to as AlScN, or ASN). The piezoelectric layer 130 may be as described in certain patent applications incorporated by reference above (e.g., U.S. Patent Application Publication 20140132117; and U.S. patent application Ser. No. 14/191,771). Notably, By way of illustration, the doping concentration of scandium is generally in the range of approximately 0.5 atomic percent (0.5%) to less than approximately 10.0 atomic percent (10%). In certain embodiments, the doping concentration of scandium is in the range of approximately 3.0% (atomic percent) to approximately 18.0% (atomic percent). For purposes of clarity, the atomic consistency of an MN piezoelectric layer doped to 3.0% Sc may then be represented as Al_{0.47}N_{0.50}Sc_{0.03}.

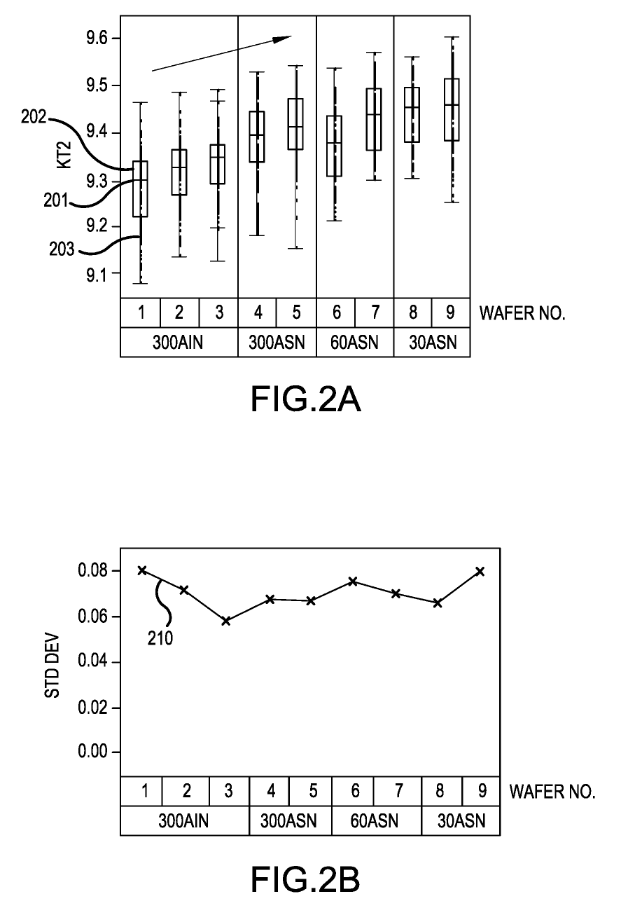

By the present teachings, the seed layer 121 fosters the growth of a highly textured ASN piezoelectric layer 130, thereby increasing the coupling coefficient (kt²), and as described more fully below, improves the quality factor (Q), increases the resistance at parallel resonance (Rp), and decreases the resistance at series resonance (Rs) of the BAW resonator device 100. More particularly, to an extent the coupling coefficient (kt²) of the piezoelectric layer 130 increases as the thickness of the seed layer 121 decreases. To this end, and as additionally described below in connection with FIGS. 2A˜2B, providing a seed layer 121 having a thickness of 150 Angstroms (Å) results in the formation of piezoelectric layer 130 that has a coupling coefficient (kt²) that is greater than if seed layer 121 had a thickness of 300 Å. Similarly, providing a seed layer 121 having a thickness of 60 Å results in the formation of piezoelectric layer 130 that has a coupling coefficient (kt²) that is greater than if seed layer 121 had a thickness of 150 Å; and providing a seed layer 121 having a thickness of 30 Å results in the formation of piezoelectric layer 130 that has a coupling coefficient (kt²) that is greater than if seed layer 121 had a thickness of 60 Å.

The impact of the reduction of the thickness of the seed layer 121 on the improvement in the coupling coefficient (kt²) is believed to result from a better lattice match between the seed layer 121 and the material used for the first electrode 120. As such, the seed layer 121 provides a better template that fosters growth of improved quality scandium doped ALN on top of the first electrode 120. To this end, in an illustrative embodiment, during growth of the seed layer 121, approximately the first 10 Å, of the seed layer (e.g., ASN) is comparatively amorphous. As the growth continues, a more defined lattice structure forms in what is known as a transition region. This transition is believed to begin when the thickness increases beyond approximately 20 Å. Eventually, as growth continues, the transition to a complete lattice structure of the material of the seed layer 121 (e.g., the lattice structure of ASN) subsides until a complete lattice structure is realized. Notably, the greater the thickness of the seed layer 121 is, the more complete the lattice structure is, and the less the seed layer 121 resembles the incomplete lattice structure of the transition stage of growth. As will become clearer as the present description continues, at thicknesses above approximately 150 Å, and certainly at thicknesses above 300 Å, the lattice structure of the seed layer 121 is comparatively complete. However, the lattice constant of the seed layer 121 with thicknesses in the so-called transition range is a better match to the lattice constant of the material used for the first electrode 120, which is, for example molybdenum. This improvement in lattice match is believed to reduce the strain between the lattices of the first electrode 120, and the seed layer 121, and thereby provides a better template for the piezoelectric layer 130 grown over the first electrode 120. Because a better template is provided by the material of the seed layer 121 during transition from amorphous to single-crystal material, the C-axis of the piezoelectric layer 130 is highly oriented, and therefore highly textured. Of course, the more highly textured the piezoelectric region is, the greater the coupling coefficient (kt²) of the piezoelectric layer 130, and the higher the quality (Q) factor of the BAW resonator device 100. Accordingly, decreasing the thickness of the seed layer 121 (but not decreasing the thickness so the seed layer 121 is substantially amorphous), provides a more highly textured piezoelectric layer 130 with an improved coupling coefficient (kt²), and improved Q. Quantitatively, in certain embodiments, the improvements in the coupling coefficient (kt²) are realized by providing a seed layer 121 having a thickness of greater than approximately 10 Å to less than approximately 300 Å. In other representative embodiments, the seed layer 121 has a thickness in the range of 30 Å to approximately 150 Å. In yet other representative embodiments, the seed layer 121 has a thickness in the range of 30 Å to approximately 60 Å.

As noted above, the increase in coupling coefficient kt² realized by including seed layer 121 in the acoustic stack 105 of BAW resonator device 100 results in improved Q, and attendant parameters Rp and Rs of the BAW resonator device 100. In addition, standard deviation of the coupling coefficients kt² of the BAW resonators across the BAW resonator device wafer (before singulation) generally decreases as the thickness of the seed layer 121 decreases, such that the coupling coefficients kt² are more constant across the BAW resonator device wafer, which is not always the case for known BAW resonator device wafers with undoped AlN piezoelectric layers. FIG. 2A is a diagram showing effective coupling coefficients kt² of BAW resonator devices as a function of seed layer thickness, and FIG. 2B is a diagram showing standard deviations of effective coupling coefficients kt² across wafers, each of which comprises multiple BAW resonator devices, as a function of seed layer thickness. In both diagrams of FIGS. 2A and 2B, one set of data is for an acoustic stack with a 300 Å seed layer disposed beneath the first electrode, where the seed layer and the piezoelectric material (i.e., AlN) are not doped with Sc. For purposes of illustration, the seed layer (if any) would be effectively the same as the seed layer 121, discussed above with reference to FIG. 1. Further, the acoustic stacks including the respective seed layers (if any) would be effectively the same structurally as the acoustic stack 105.

Referring to FIG. 2A, characteristics of four sample wafers were measured for each of four seed interlayer configurations. Sample wafers 1-3 include AlN seed layers each having a thickness of approximately 300 Å; sample wafers 4-5 include ASN seed layers each having a thickness of approximately 300 Å; sample wafers 6-7 include ASN seed layers each having a thickness of approximately 60 Å; and sample wafers 8-9 include ASN seed layers each having a thickness of approximately 30 Å. The seed layers are disposed between a silicon (Si) substrate, and a first electrode comprising molybdenum (Mo), with the first electrode disposed on (i.e., directly on) the seed layer.

Each of the sample wafers 1-9 has corresponding graphical information arranged vertically over the numbers identifying the sample wafers 1-9. For purposes of illustration, sample wafer 1 will be referenced to explain the corresponding graphical information, which explanation likewise applies to the other sample wafers in the coupling coefficient diagrams described below, so this explanation will not be repeated.

Referring to sample wafer 1 in FIG. 2A, a range of discrete measured values (in this case, a range of measured coupling coefficients kt² corresponding to multiple BAW resonator devices in the sample wafer 1) is indicated by the box 202, a median value of the range of discrete measured values (e.g., the median coupling coefficient kt²) is indicated by marker 201, and the coupling coefficient outliers of the measured values of the multiple BAW resonator devices across the sample wafer 1 are indicated by vertical line 203. In the depicted example of sample wafer 1, the coupling coefficient kt² values range from about 9.21 percent to about 9.32 percent as shown by box 202, the median coupling coefficient kt² value is about 9.3 percent as shown by marker 201, and the coupling coefficient outlier values range from about 9.05 percent to about 9.46 percent as shown by vertical line 203.

FIG. 2A depicts improvement (depicted by the arrow) in the coupling coefficients kt² of BAW resonator devices with reduced seed layer thickness. To this end, data depicted are for seed layers approximately 300 Å thick undoped AlN (sample wafers 1-3); and wafers having ASN seed layers approximately 300 Å thick (sample wafers 4-5), ASN seed layers approximately 60 Å thick (sample wafers 6-7), and ASN seed layers approximately 30 Å thick (sample wafers 7-9). Sample wafers 4-5 have median coupling coefficient kt² values between 9.39 percent and 9.41 percent, while sample wafers 1-3 have median coupling coefficient kt² values of approximately 9.3 percent and 9.34 percent. Sample wafers 6-7 have median coupling coefficient values of approximately 9.35 and approximately 9.44 percent. Finally, sample wafers 7-9 have median coupling coefficient values kt² of approximately 9.44 percent and 9.46 percent. Moreover, as shown by the line 210 in FIG. 2B (which is formed by X's corresponding to the sample wafers 1-9, respectively), sample wafers 1-3 have standard deviations of approximately 0.055 percent to 0.080; sample wafers 4-5 has a standard deviation of approximately 0.063 percent; sample wafers 6-7 have standard deviations of about 0.065 percent and 0.07 percent; sample wafers 8-9 have standard deviations of about 0.063 percent and 0.08 percent, where the lower standard deviations are more desirable.

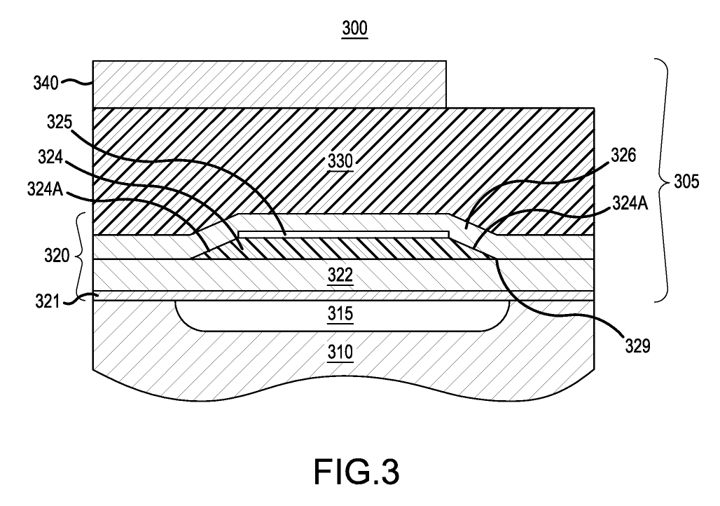

FIG. 3 is a cross-sectional view of a BAW resonator device, which includes an electrode having a buried temperature compensating layer and seed interlayer, according to a representative embodiment.

Referring to FIG. 3, illustrative BAW resonator device 300 includes acoustic stack 305 formed on substrate 310. The substrate 310 may be formed of various types of materials compatible with wafer-scale processes, such as silicon (Si), gallium arsenide (GaAs), indium phosphide (InP), silicon dioxide, alumina, or the like, thus reducing the cost of the final part. In the depicted embodiment, the substrate 310 defines a cavity 315 formed beneath the acoustic stack 305 to provide acoustic isolation, such that the acoustic stack 305 is suspended over an air space to enable mechanical movement. In alternative embodiments, the substrate 310 may be formed with no cavity 315, for example, using SMR technology. For example, the acoustic stack 305 may be formed over an acoustic mirror or a distributed Bragg reflector (DBR) (not shown), having alternating layers of high and low acoustic impedance materials, formed in or on the substrate 310. An acoustic mirror may be fabricated according to various techniques, an example of which is described in U.S. Pat. No. 7,358,831 to Larson, III, et al., the disclosure of which is hereby incorporated by reference in its entirety.

The acoustic stack 305 includes piezoelectric layer 330 formed between composite first (bottom) electrode 320 and second (top) electrode 340. In the depicted embodiment, the composite first electrode 320 includes multiple layers, and thus is referred to as a “composite electrode.” The composite first electrode 320 includes a base electrode layer 322 (first electrically conductive layer), a buried temperature compensation layer 324, a thin seed interlayer 325, and a conductive interposer layer 326 (second electrically conductive layer) stacked sequentially on the substrate 310. In a representative embodiment, the base electrode layer 322 and/or the conductive interposer layer 326 are formed of electrically conductive materials, such as various metals compatible with wafer processes, including tungsten (W), molybdenum (Mo), aluminum (Al), platinum (Pt), ruthenium (Ru), niobium (Nb), or hafnium (Hf), for example. In certain representative embodiments, at least one of the electrically conductive layers of the base electrode layer 322 and the conductive interposer layer 326 is made of a material that has a positive temperature coefficient. In accordance with a representative embodiment, the material having the positive temperature coefficient is an alloy. Illustratively, the alloy may be one of nickel-iron (Ni—Fe), niobium-molybdenum (NbMo) and nickel-titanium (NiTi).

The acoustic stack 305 also comprises a seed layer 321 disposed over the substrate 310. The base electrode layer 322 is disposed on (i.e., directly on) the seed layer 321, which is provided in the customary fabrication sequence of the acoustic stack.

In the representative embodiment, the thin seed interlayer 325 is disposed over the buried temperature compensation layer 324 and beneath the conductive interposer layer 326, and the piezoelectric layer 330 is disposed over the conductive interposer layer 326. The piezoelectric layer 330 is formed of AlN material doped with Sc (referred to as AlScN). In various embodiments, the AlScN piezoelectric layer 330 may include concentration of Sc in a range of approximately 5.0 atomic percent to approximately 12 atomic percent of the piezoelectric material, for example. The seed interlayer 325 functions as a seed interlayer to foster growth of a highly textured AlScN piezoelectric layer 330, and increases the coupling coefficient kt². More particularly, the coupling coefficient kt² increases as the thickness of the seed interlayer 325 decreases. The increase in coupling coefficient kt² helps to offset the reduction in coupling coefficient kt² resulting from inclusion of the buried temperature compensation layer 324. In addition, standard deviation of the coupling coefficients kt² of the acoustic resonators across the BAW resonator device wafer (before singulation) generally decreases as the thickness of the seed interlayer 325 decreases, such that the coupling coefficients kt² are more constant across the BAW resonator device wafer, which is not the case for conventional BAW resonator device wafers with undoped AlN piezoelectric layers.

The buried temperature compensation layer 324 may be formed of various materials compatible with wafer processes, including silicon dioxide (SiO₂), borosilicate glass (BSG), fluorine doped SiO₂, chromium oxide (Cr₍ₓ₎O_{(y)}) or tellurium oxide (TeO₍ₓ₎), for example, which have positive temperature coefficients that offset at least a portion of the negative temperature coefficients of the piezoelectric layer 330 and the conductive material in the composite first electrode 320 and the second electrode 340. The seed interlayer 325, or seed interlayer, causes a highly textured piezoelectric layer 330 to grow with a highly oriented C-axis, substantially perpendicular to a growth surface of the conductive interposer layer. The seed interlayer 325 may be formed of AlN, for example. Alternatively, the seed interlayer 325 may be formed of materials with a hexagonal crystal structure (such as titanium, ruthenium), or a composition of the same piezoelectric material (e.g., AlScN) as the piezoelectric layer 330 and a hexagonal crystal structure material. As mentioned above, the thinner the seed interlayer 325, the greater the increase in coupling coefficient kt² of the acoustic stack 305. Thus, the seed interlayer 325 has a thickness in a range of about 5 Anstroms (Å) to about 150 Å. In an embodiment, the seed interlayer 325 has a thickness in a range between about 20 Å and about 50 Å, for example. Accordingly, the coupling coefficient kt² is increased (improved) by incorporating Sc doped AlN material as the piezoelectric layer 330 and by inclusion of the seed interlayer 325, collectively offsetting at least a portion of the reduction in the coupling coefficient kt² caused by inserting the buried temperature compensation layer 324 in the acoustic stack 305.

Notably, without seed interlayer 325, a piezoelectric layer 330 formed of Sc doped AlN has poor growth quality on the composite first electrode 320 (including buried temperature compensation layer 324), than grown on a first electrode with no temperature compensation. That is, the material selected for the conductive interposer layer 326 should be selected so as to not adversely impact the quality of the crystalline structure of the piezoelectric layer 330, as it is desirable to provide a highly textured (well oriented C-axis) piezoelectric layer 330 in the acoustic stack 305. It has thus been beneficial to use a material for the conductive interposer layer 326 that will allow growth of a highly textured piezoelectric layer 330. However, the addition of the seed interlayer 325 can reduce or eliminate the need for selecting a material for the conductive interposer layer 326 that does not adversely impact the crystalline orientation of the piezoelectric layer 330. In various embodiments, the base electrode layer 322, the conductive interposer layer 326 and the second electrode 340 may be made from one or more materials having a positive temperature coefficient to further reduce or substantially prevent the adverse impact on frequency at higher temperatures of operation. That is, the positive temperature coefficient of the selected base electrode layer 322, or the conductive interposer layer 326, or both, beneficially offsets negative temperature coefficients of other materials in the acoustic stack 305, including for example the piezoelectric layer 330, the second electrode 340, and any other layer of the acoustic stack that has a negative temperature coefficient. Beneficially, the inclusion of one or more layers of materials having the positive temperature coefficient for electrically conductive layers in the acoustic stack allows the same degree of temperature compensation with a thinner buried temperature compensation layer 324.

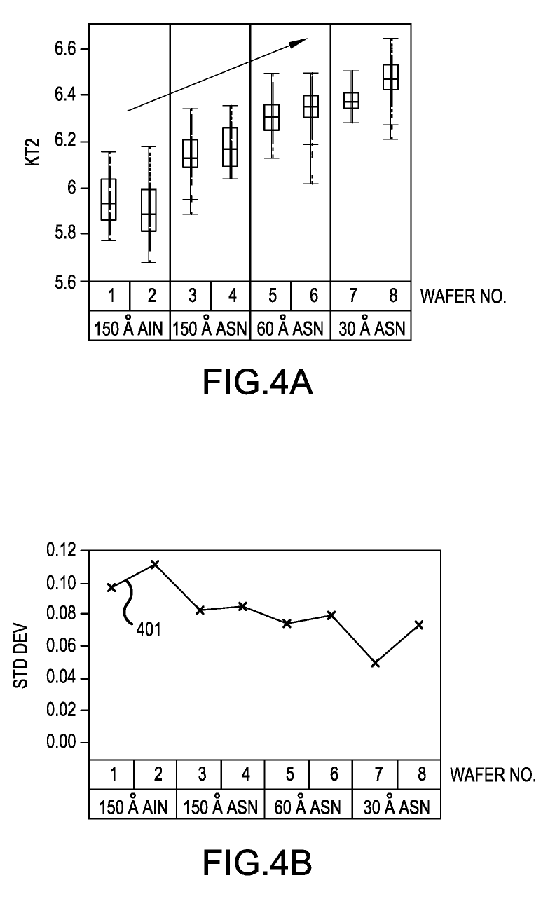

By the present teachings, the seed interlayer 325 fosters the growth of a highly textured ASN piezoelectric layer 330, thereby increasing the coupling coefficient (kt²), and as described more fully below, improves the quality factor (Q), increases the resistance at parallel resonance (Rp), and decreases the resistance at series resonance (Rs) of the BAW resonator device 300. More particularly, to an extent the coupling coefficient (kt²) of the piezoelectric layer 330 increases as the thickness of the seed interlayer 325 decreases. To this end, and as additionally described below in connection with FIGS. 4A-4B, providing a seed interlayer 325 having a thickness of 150 Angstroms (Å) results in the formation of piezoelectric layer 330 that has a coupling coefficient (kt²) that is greater than if seed interlayer 325 had a thickness of 300 Å. Similarly, providing a seed interlayer 325 having a thickness of 60 Å results in the formation of piezoelectric layer 330 that has a coupling coefficient (kt²) that is greater than if seed interlayer 325 had a thickness of 150 Å; and providing a seed interlayer 325 having a thickness of 30 Å results in the formation of piezoelectric layer 330 that has a coupling coefficient (kt²) that is greater than if seed interlayer 325 had a thickness of 60 Å.

Furthermore, the impact of the reduction of the thickness of the seed interlayer 325 on the improvement in the coupling coefficient (kt²) is believed to result from a better lattice match between the seed interlayer 325 and the material used for the composite first electrode 320. As such, the seed interlayer 325 provides a better template that fosters growth of improved quality scandium doped ALN on top of the conductive interposer layer 326. To this end, in an illustrative embodiment, during growth of the seed interlayer 325, the first 10 Å, of the seed layer (e.g., ASN) is comparatively amorphous. As the growth continues, a more defined lattice structure forms in what is known as a transition region. This transition is believed to begin when the thickness increases beyond approximately 10 Å. Eventually, as growth continues, the transition to a complete lattice structure of the material of the seed interlayer 325 (e.g., the lattice structure of ASN) subsides until a complete lattice structure is realized. Notably, the greater the thickness of the seed interlayer 325 is, the more complete the lattice structure is, and the less the seed interlayer 325 resembles the incomplete lattice structure of the transition stage of growth. As will become clearer as the present description continues, at thicknesses above approximately 150 Å, and certainly at thicknesses above 300 Å, the lattice structure of the seed interlayer 325 is comparatively complete. However, the lattice constant of the seed interlayer 325 with thicknesses in the so-called transition range is a better match to the lattice constant of the material used for the conductive interposer layer 326, which is, for example molybdenum. This improvement in lattice match is believed to reduce the strain between the lattices of the conductive interposer layer 326, and the seed interlayer 325, and thereby provides a better template for the piezoelectric layer 330 grown over the conductive interposer layer 326. Because a better template is provided by the material of the seed interlayer 325 during transition from amorphous to single-crystal material, the C-axis of the piezoelectric layer 330 is highly oriented, and therefore highly textured. Of course, the more highly textured the piezoelectric region is, the greater the coupling coefficient (kt²) of the piezoelectric layer 330, and the higher the quality (Q) factor of the BAW resonator device 300. Accordingly, decreasing the thickness of the seed interlayer 325 (but not decreasing the thickness so the seed interlayer 325 is amorphous) provides a more highly textured piezoelectric layer 330 with an improved coupling coefficient (kt²), and improved Q. Quantitatively, in certain embodiments, the improvements in the coupling coefficient (kt²) are realized by providing a seed interlayer 325 having a thickness of greater than approximately 20 Å to less than approximately 300 Å. In other representative embodiments, the seed interlayer 325 has a thickness in the range of 30 Å to approximately 150 Å. In yet other representative embodiments the seed interlayer 325 has a thickness in the range of 30 Å to approximately 60 Å.

As noted above, the increase in coupling coefficient kt² realized by including seed interlayer 325 in the acoustic stack 305 of BAW resonator device 300 results in improved Q, and attendant parameters Rp and Rs of the BAW resonator device 300. In addition, standard deviation of the coupling coefficients kt² of the BAW resonators across the BAW resonator device wafer (before singulation) generally decreases as the thickness of the seed interlayer 325 decreases, such that the coupling coefficients kt² are more constant across the BAW resonator device wafer, which is not always the case for known BAW resonator device wafers with undoped AlN piezoelectric layers. FIG. 4A is a diagram showing effective coupling coefficients kt² of BAW resonator devices as a function of seed layer thickness, and FIG. 4B is a diagram showing standard deviations of effective coupling coefficients kt² across wafers, each of which comprises multiple BAW resonator devices, as a function of seed layer thickness. In both diagrams of FIGS. 4A and 4B, for all different splits, the seed layer 321 is the same (i.e., 300 Å un-doped AlN). The splits come from the different material and thicknesses of seed interlayer 325. One set of data is for an acoustic stack with a 150 Å seed interlayer 325 disposed beneath conductive interposer layer 326 in composite first electrode 320, where the seed layer is not doped with Sc. For purposes of illustration, the seed layer (if any) would be effectively the same as the seed interlayer 325, discussed above with reference to FIG. 3. Further, the acoustic stacks including the respective seed layers (if any) would be effectively the same structurally as the acoustic stack 305.

In various embodiments, the base electrode layer 322 and the conductive interposer layer 326 are formed of different conductive materials, where the base electrode layer 322 is formed of a material having relatively lower conductivity and relatively higher acoustic impedance, and the conductive interposer layer 326 is formed of a material having relatively higher conductivity and relatively lower acoustic impedance. For example, the base electrode layer 322 may be formed of W, Ni—Fe, NbMo, or NiTi, and the conductive interposer layer 326 may be formed of Mo, although other materials and/or combinations of materials may be used without departing from the scope of the present teachings. In accordance with a representative embodiment, the selection of the material for the conductive interposer layer 326 is made to foster growth of highly textured piezoelectric material that forms piezoelectric layer 330. Further, in various embodiments, the base electrode layer 322 and the conductive interposer layer 326 may be formed of the same conductive material, without departing from the scope of the present teachings.

As should be appreciated by one of ordinary skill in the art, the electrical conductivity and the acoustic impedance depend on the material selected for the positive temperature coefficient material provided in the acoustic stack 305. Moreover, the acoustic impedance and electrical conductivity of the positive temperature coefficient material will impact its location in the acoustic stack 305. Typically, it is useful to provide a positive temperature coefficient material having a comparatively high acoustic impedance in order to achieve a higher acoustic coupling coefficient kt², thereby allowing a comparatively thin piezoelectric layer 330 to be provided in the acoustic stack 305. Moreover, it is useful to provide a positive temperature coefficient material having a comparatively low electrical resistance to avoid ohmic (resistive) losses in the BAW resonator device 300. Finally, the present teachings contemplate the use of a multi-layer structure for the layer(s) of the acoustic stack 305 having a positive temperature coefficient to achieve comparatively high acoustic impedance and comparatively low electrical conductivity.

The buried temperature compensation layer 324 is considered a buried temperature compensating layer, in that it is formed between the base electrode layer 322 and the conductive interposer layer 326. The buried temperature compensation layer 324 is therefore separated or isolated from the piezoelectric layer 330 by the conductive interposer layer 326, and is otherwise sealed in by the connection between the conductive interposer layer 326 and the base electrode layer 322. Accordingly, the buried temperature compensation layer 324 is effectively buried within the composite first electrode 320.

As noted previously, at least one of the base electrode layer 322, the conductive interposer layer 326 and the second electrode 340 may be made of a material that has a positive temperature coefficient. As such, the second electrode 340 may be made of material having the positive temperature coefficient, while one or both of the base electrode layer 322 and the conductive interposer layer 326 are made of a material having a negative temperature coefficient. As noted above, the material having a positive temperature coefficient may be an alloy. Illustratively, the alloy may be one of nickel-iron (Ni—Fe), niobium-molybdenum (NbMo) and nickel-titanium (NiTi). The positive temperature coefficient of the second electrode 340 beneficially offsets negative temperature coefficients of other materials in the acoustic stack 305, including for example the piezoelectric layer 330 and any other layer of the acoustic stack 305 that has a negative temperature coefficient. Beneficially, the inclusion of one or more layers of materials having the positive temperature coefficient for electrically conductive layers in the acoustic stack 305 allows the same degree of temperature compensation with a thinner buried temperature compensation layer 324.

As shown in the representative embodiment of FIG. 3, the buried temperature compensation layer 324 and the seed interlayer 325 do not extend the full width of the acoustic stack 305. Also, the seed interlayer 325 does not extend the full width of the buried temperature compensation layer 324, but rather is positioned only on a portion of the top surface that is substantially parallel to the bottom surface of the piezoelectric layer 330. Thus, the conductive interposer layer 326, which is formed on the top surface of the seed interlayer 325 and the side surfaces of the buried temperature compensation layer 324, contacts the top surface of the base electrode layer 322, as indicated for example by reference number 329. Therefore, a DC electrical connection is formed between the conductive interposer layer 326 and the base electrode layer 322. By DC electrically connecting with the base electrode layer 322, the conductive interposer layer 326 effectively “shorts” out a capacitive component of the buried temperature compensation layer 324, thus increasing the coupling coefficient kt² of the BAW resonator device 300. In addition, the conductive interposer layer 326 provides a barrier that prevents oxygen in the buried temperature compensation layer 324 from diffusing into the piezoelectric layer 330, preventing contamination of the piezoelectric layer 330.

Also, in the depicted embodiment, the buried temperature compensation layer 324 has tapered edges 324A, which enhance the DC electrical connection between the conductive interposer layer 326 and the base electrode layer 322. That is, at least one tapered edge 324A enabling at least a portion of the conductive interposer layer 326 to contact the base electrode layer 322. In addition, the tapered edges 324A enhance the mechanical connection between the conductive interposer layer 326 and the base electrode layer 322, which improves the sealing quality, e.g., for preventing oxygen in the buried temperature compensation layer 324 from diffusing into the piezoelectric layer 330. In alternative embodiments, the edges of the buried temperature compensation layer 324 are not tapered, but may be substantially perpendicular to the top and bottom surfaces of the buried temperature compensation layer 324, for example, without departing from the scope of the present teachings. In this configuration, the seed interlayer 325 may extend the full width or a portion of the full width of the buried temperature compensation layer 324.

The piezoelectric layer 330 is formed over the top surface of the conductive interposer layer 326. As mentioned above, the piezoelectric layer 330 is formed of AlN doped with Sc, the concentration of which is in a range of approximately 5.0 atomic percent to approximately 12 atomic percent of the material in the piezoelectric layer 330. The piezoelectric layer 330 may be grown or deposited over the upper surface of the conductive interposer layer 326 in composite first electrode 320 using one of a number of known methods, such as sputtering, for example, although the piezoelectric layer 330 may be fabricated according to any various techniques compatible with wafer processes. The thickness of the piezoelectric layer 330 may range from about 1000 Å to about 100,000 Å, for example, although the thickness may vary to provide unique benefits for any particular situation or to meet application specific design requirements of various implementations, as would be apparent to one of ordinary skill in the art.

The second electrode 340 is formed on the top surface of the piezoelectric layer 330. The second electrode 340 is formed of an electrically conductive material compatible with wafer processes, such as Mo, W, Al, Pt, Ru, Nb, Hf, or the like. In an embodiment, the second electrode 340 is formed of the same material as the base electrode layer 322 of the composite first electrode 320. However, in various embodiments, the second electrode 340 may be formed of the same material as only the conductive interposer layer 326; the second electrode 340, the conductive interposer layer 326 and the base electrode layer 322 may all be formed of the same material; or the second electrode 340 may be formed of a different material than both the conductive interposer layer 326 and the base electrode layer 322, without departing from the scope of the present teachings.

The second electrode 340 may further include a passivation layer (not shown), which may be formed of various types of materials, including AlN, silicon carbide (SiC), BSG, SiO₂, SiN, polysilicon, and the like. Illustratively, the passivation layer may be as described by Miller et al., U.S. Pat. No. 8,330,556 (issued Dec. 11, 2012), which is hereby incorporated by reference in its entirety. The thickness of the passivation layer must be sufficient to insulate all layers of the acoustic stack 305 from the environment, including protection from moisture, corrosives, contaminants, debris and the like. The composite first 320 and second electrode 340 are electrically connected to external circuitry via contact pads (not shown), which may be formed of a conductive material, such as gold, gold-tin alloy or the like.

In an embodiment, an overall first thickness of the composite first electrode 320 is substantially the same as an overall second thickness of the second electrode 340, although in other embodiments the first and second overall thicknesses may differ from one another, as shown in FIG. 3. The thickness of each of the composite first electrode 320 and the second electrode 340 may range from about 600 Å to about 30000 Å, for example, although the thicknesses may vary to provide unique benefits for any particular situation or to meet application specific design requirements of various implementations, as would be apparent to one of ordinary skill in the art.

The multiple layers of the composite first electrode 320 have corresponding thicknesses. For example, the thickness of base electrode layer 322 may range from about 400 Å to about 29,900 Å, the thickness of buried temperature compensation layer 324 may range from about 100 Å to about 5000 Å, the thickness of seed interlayer 325 may range from about 5 Å to about 150 Å, and the thickness of conductive interposer layer 326 may range from about 100 Å to about 10000 Å. As a general consideration, the thickness of the layers of the acoustic stack 305 depend not only on the thickness of the buried temperature compensation layer 324, but also on the desired acoustic coupling coefficient kt², the targeted temperature response profile, and the frequency target of the BAW resonator device 300. As such, the extent to which the thickness of the buried temperature compensation layer 324 can be reduced through the inclusion of one or more layers of the acoustic stack 305 that have a positive temperature coefficient depends on the magnitude of the positive temperature coefficient of the material used, the thickness(es) of the one or more layers of the acoustic stack 305 that have a positive temperature coefficient, the desired acoustic coupling coefficient kt², and the desired frequency target of the acoustic stack 305.

Each of the layers of the composite first electrode 320 may be varied to produce different characteristics with respect to temperature coefficients and coupling coefficients, while the overall first thickness of the composite first electrode 320 may be varied with the overall second thickness of the second electrode 340. As such, the first thickness of the composite first electrode 320 and overall second thickness of the second electrode 340 may be the same, or may differ depending on the desired temperature coefficient, acoustic coupling coefficient kt² and frequency target of the acoustic stack 305. Similarly, the thickness of the buried temperature compensation layer 324 may be varied to affect the overall temperature coefficient of the acoustic stack 305, and the relative thicknesses of the base electrode layer 322 and the conductive interposer layer 326 may be varied to affect the overall coupling coefficient of the BAW resonator device 300.

Like seed layers described above in connection with FIGS. 1-2B, an increase in coupling coefficient kt² realized by including the seed interlayer 325 in the acoustic stack 305 of BAW resonator device 300 results in improved Q, and attendant parameters Rp and Rs of the BAW resonator device 300. In addition, standard deviation of the coupling coefficients kt² of the BAW resonators across the BAW resonator device wafer (before singulation) generally decreases as the thickness of the seed interlayer 325 decrease, such that the coupling coefficients (kt²) are more constant across the BAW resonator device wafer, which is not always the case for known BAW resonator device wafers with undoped piezoelectric layers. FIG. 4A is a diagram showing effective coupling coefficients kt² of BAW resonator devices as a function of seed layer thickness, and FIG. 4B is a diagram showing standard deviations of effective coupling coefficients kt² across wafers, each of which comprises multiple BAW resonator devices, as a function of seed layer thickness.

In both diagrams of FIGS. 4A and 4B, the seed layer 321 underneath base electrode layer 322 of composite first electrode 320 is always 300 Å un-doped AlN seed for all different splits. The difference in each of the splits come from the seed interlayer 325 which is underneath conductive interposer layer 326. Specifically, in FIGS. 4A and 4B, wafers 1-2 have undoped 150A seed interlayer 325 between buried temperature compensation layer 324 and conductive interposer layer 326. By contrast, wafers 3-8 have a doped seed layer (i.e., seed interlayer 325) immediately beneath the conductive interposer layer 326 of ASN. Notably, the doping level of the seed interlayer 325 is substantially the same as the piezoelectric layer 330 formed thereover. As such, the seed interlayer 325 has a doping level of approximately 5.0 atomic percent to approximately 18.0 atomic percent. Moreover, the seed interlayer 325 has a thicknesses of approximately 30 Å to approximately 150 Å. Wafers 3-4 have a doped seed interlayer (i.e., seed interlayer 325) having a thickness of 150 Å; wafers 5-6 have a doped seed interlayer (i.e., seed interlayer 325) having a thickness of 60 Å; and wafers 7-8 have a doped seed interlayer (i.e., seed interlayer 325) having a thickness of 30 Å.

As can be seen following the arrow of FIG. 4A, the median values of the coupling coefficients (kt²) steadily increase, with decreasing thickness of the seed interlayer. In addition, the coupling coefficients (kt²) also increases when the seed interlayer 325 is changed from 150 Å of un-doped AlN seed to 150 Å of Sc doped AlN seed. Moreover, as depicted in FIG. 4B, some improvements are made in the standard deviations across the BAW resonator device wafer, which is not always the case for known BAW resonator device wafers (with un-doped piezoelectric material layer) with decreasing thickness of undoped AlN seed layers. In addition, the variation in the coupling coefficient (kt²) across a wafer is also improved when the seed interlayer 325 is changed from 150 Å un-doped AlN seed to 150 Å Sc doped AlN.

Finally, as alluded to above, improvements in the acoustic coupling coefficient (kt²) results in a desired increase in Rp and a desired decrease in Rs. Notably, it can be shown, based on circuit level representation of a BAW resonator: Rp=kt2*Qp*Zo/1.2; and Rs=1.2*Zo/(kt2*Qs), where Zo=50 ohm is a characteristic impedance, and Qs and Qp are Q-values of the circuit at Fs and Fp, respectively. As such, for comparatively constant Qs and Qp, as kt² increases, Rp increases and Rs decreases.

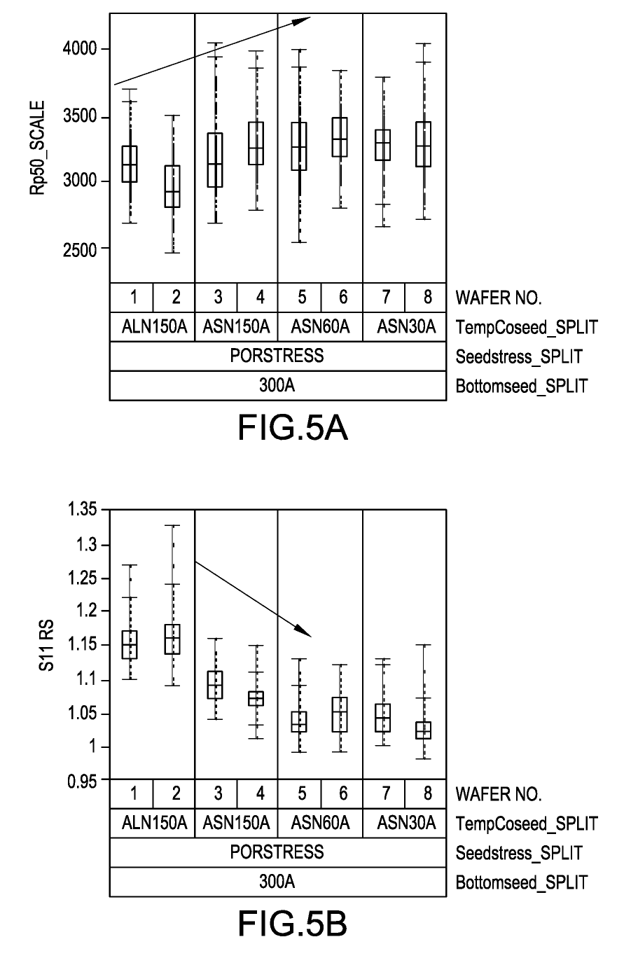

Turning to FIGS. 5A and 5B, wafers 1-8 are the same as those of FIGS. 4A-4B. As depicted in FIG. 5A, Rp generally increases with decreasing seed interlayer thickness. Similarly, as depicted in FIG. 5B, Rs generally decreases with decreasing seed interlayer thickness.

The various components, materials, structures and parameters are included by way of illustration and example only and not in any limiting sense. In view of this disclosure, those skilled in the art can implement the present teachings in determining their own applications and needed components, materials, structures and equipment to implement these applications, while remaining within the scope of the appended claims.

1. A bulk acoustic wave (BAW) resonator comprising:
a seed layer disposed over a substrate, the seed layer having a thickness in the range of approximately 30 Å to approximately 150 Å;
a first electrode disposed on the seed layer; and
a second electrode disposed over a piezoelectric layer.

2. The BAW resonator of claim 1, wherein the piezoelectric layer comprises aluminum nitride (AlN) doped with scandium (Sc).

3. The BAW resonator of claim 2, wherein the seed layer comprises a piezoelectric material.

4. The BAW resonator of claim 3, wherein the seed layer comprises scandium-doped aluminum nitride (ASN).

5. The BAW resonator of claim 2, wherein a concentration of scandium (Sc) is in a range of approximately 5.0 atomic percent to approximately 18 atomic percent of the piezoelectric material.

6. The BAW resonator of claim 4, wherein a concentration of scandium (Sc) is in a range of approximately 5.0 atomic percent to approximately 18 atomic percent of the piezoelectric material.

7. A bulk acoustic wave (BAW) resonator comprising:
a seed layer disposed over a substrate, the seed layer having a thickness in the range of approximately 30 Å to approximately 60 Å;
a first electrode disposed on the seed layer; and
a second electrode disposed over a piezoelectric layer.

8. The BAW resonator of claim 7, wherein the piezoelectric layer comprises aluminum nitride (AlN) doped with scandium (Sc).

9. The BAW resonator of claim 8, wherein the seed layer comprises a piezoelectric material.

10. The BAW resonator of claim 8, wherein the seed layer comprises scandium-doped aluminum nitride (ASN).

11. The BAW resonator of claim 8, wherein a concentration of scandium (Sc) is in a range of approximately 5.0 atomic percent to approximately 18 atomic percent of the piezoelectric material.

12. The BAW resonator of claim 10, wherein a concentration of scandium (Sc) is in a range of approximately 5.0 atomic percent to approximately 18 atomic percent of the piezoelectric material.

13. A bulk acoustic wave (BAW) resonator comprising:
a seed layer disposed over a substrate, the seed layer having a thickness in the range of approximately 30 Å to approximately 60 Å;
a composite first electrode disposed over a substrate, the composite first electrode comprising:
a base electrode layer disposed on the seed layer;
a temperature compensation layer disposed on the base electrode layer;
a seed interlayer disposed on the temperature compensation layer, the seed interlayer having a thickness between about 30 Å and about 60 Å; and
a conductive interposer layer disposed on at least the seed interlayer, at least a portion of the conductive interposer layer contacting the base electrode layer;
a piezoelectric layer disposed on the composite first electrode, the piezoelectric layer comprising a piezoelectric material doped with scandium (Sc) for improving piezoelectric properties of the piezoelectric layer; and
a second electrode disposed on the piezoelectric layer,
wherein the piezoelectric layer has a negative temperature coefficient and the temperature compensation layer has a positive temperature coefficient that at least partially offsets the negative temperature coefficient of the piezoelectric layer.

14. The BAW resonator of claim 13, wherein the piezoelectric layer comprises aluminum nitride (AlN) doped with scandium (Sc).

15. The BAW resonator of claim 14, wherein the seed interlayer comprises a piezoelectric material.

16. The BAW resonator of claim 15, wherein the seed interlayer comprises scandium-doped aluminum nitride (ASN).

17. The BAW resonator of claim 15, wherein the seed layer comprises piezoelectric material.

18. The BAW resonator of claim 17, wherein the seed interlayer comprises scandium-doped aluminum nitride (ASN).

19. The BAW resonator of claim 14, wherein a concentration of scandium (Sc) is in a range of approximately 5.0 atomic percent to approximately 18 atomic percent of the piezoelectric material.

20. The BAW resonator of claim 16, wherein a concentration of scandium (Sc) is in a range of approximately 5.0 atomic percent to approximately 18 atomic percent of the piezoelectric material.

21. The BAW resonator of claim 18, wherein a concentration of scandium (Sc) is in a range of approximately 5.0 atomic percent to approximately 18 atomic percent of the piezoelectric material.

22. A bulk acoustic wave (BAW) resonator comprising:
a seed layer disposed over a substrate, the seed layer having a thickness in the range of approximately 30 Å to approximately 150 Å;
a composite first electrode disposed over a substrate, the composite first electrode comprising:
a base electrode layer disposed on the seed layer;
a temperature compensation layer disposed over the base electrode layer;
a seed interlayer disposed over the temperature compensation layer, the seed interlayer having a thickness between about 30 Å and about 150 Å; and
a conductive interposer layer disposed on at least the seed interlayer, at least a portion of the conductive interposer layer contacting the base electrode layer;
a piezoelectric layer disposed on the composite first electrode, the piezoelectric layer comprising a piezoelectric material doped with scandium (Sc) for improving piezoelectric properties of the piezoelectric layer; and
a second electrode disposed over the piezoelectric layer, wherein the piezoelectric layer has a negative temperature coefficient and the temperature compensation layer has a positive temperature coefficient that at least partially offsets the negative temperature coefficient of the piezoelectric layer.

23. The BAW resonator of claim 22, wherein the piezoelectric layer comprises aluminum nitride (AlN) doped with scandium (Sc).

24. The BAW resonator of claim 22, wherein the seed interlayer comprises a piezoelectric material.

25. The BAW resonator of claim 24, wherein the seed interlayer comprises scandium-doped aluminum nitride (ASN).

26. The BAW resonator of claim 22, wherein the seed layer comprises piezoelectric material.

27. The BAW resonator of claim 26, wherein the seed layer comprises scandium-doped aluminum nitride (ASN).

28. The BAW resonator of claim 23, wherein a concentration of scandium (Sc) is in a range of approximately 5.0 atomic percent to approximately 18 atomic percent of the piezoelectric material.

29. The BAW resonator of claim 25, wherein a concentration of scandium (Sc) is in a range of approximately 5.0 atomic percent to approximately 18 atomic percent of the piezoelectric material.

30. The BAW resonator of claim 27, wherein a concentration of scandium (Sc) is in a range of approximately 5.0 atomic percent to approximately 18 atomic percent of the piezoelectric material.
